(19) United States
(12) Patent Application Publication
(10) Pub. No.: US 2026/0198267 A1
(43) Pub. Date: Jul. 9, 2026

(54) Chip Removal Head, Chip Removal System and Chip Removal Method

(71) Applicant: CHONGQING KONKA PHOTOELECTRIC TECHNOLOGY RESEARCH INSTITUTE CO., LTD., Chongqing (CN)

(72) Inventors: Bin WANG, Chongqing (CN); Chun-Lung HSIAO, Chongqing (CN); Kai-lun WANG, Chongqing (CN); Ming-Ta TSAI, Chongqing (CN); Ruiqi ZHAN, Chongqing (CN)

(73) Assignee: CHONGQING KONKA PHOTOELECTRIC TECHNOLOGY RESEARCH INSTITUTE CO., LTD., Chongqing (CN)

(21) Appl. No.: 19/481,408

(22) PCT Filed: Aug. 10, 2021
(86) PCT No.: PCT/CN2021/111790

§ 371 Date: Mar. 31, 2026

(51) Int. Cl. H10P 72/78; H10H 29/01; H10P 72/00

(52) U.S. Cl. CPC H10P 72/78; H10H 29/01; H10P 72/0438

(57) ABSTRACT

A chip removal head, a chip removal system and a chip removal method are provided. The chip removal head has a heating portion and an attractive force guide portion, the heating portion including a bottom surface and a top surface, which are opposite to each other, and the bottom surface is a surface in contact with a to-be-removed chip; the heating portion is connected to an external power supply, and generates a dissociation heat under the action of the external power supply, so as to release a connection between the to-be-removed chip and an external substrate; and the attractive force guide portion is configured to guide the to-be-removed chip, for which the connection has been released, to be adsorbed on the bottom surface of the heating portion.

### TECHNICAL FIELD

The present application relates to the field of light-emitting chips, and in particular, to a chip removal head, a chip removal system and a chip removal method.

### BACKGROUND

A Micro LED (Micro Light-Emitting Diode, micro light-emitting diode) is an emerging display technology. Compared with conventional display technologies, display with the Micro LED technology as the core has the characteristics of high response speed, autonomous light-emitting, high contrast, long service life, high photoelectric efficiency, etc.

In a Micro LED industrial technology, millions or even tens of millions of Micro LED chips are transferred to a display backplane. However, due to an inevitable problem of yield in a manufacturing process, even if the yield reaches 99.999%, a large number of unqualified Micro LED chips are removed or even repaired. For example, a 4K display panel requires 25 million Micro LED chips, and even if a defect rate is 0.001%, at least 2,500 Micro LED chips need to be removed.

At present, for the removal of defective Micro LED chips on the display panel, the Micro LED chips are usually pushed off by a mechanical force, or the Micro LED chips are removed by laser, so the Micro LED chips will be damaged during a removal process, resulting in irregular splash of the Micro LED chips to be removed or fragments thereof, which leads to contamination to the entire display panel. In addition, a bonding pad connected to the Micro LED chips on the display panel is also easily damaged by an external force, such that a new Micro LED chip disposed at this position thereafter cannot be normally electrically connected to the display backplane, thus affecting subsequent repairs.

Therefore, how to remove the defective Micro LED chips without causing contamination to the display panel and damage to the bonding pad is an urgent problem to be solved at present.

### SUMMARY

### Technical Problem

In view of the above-mentioned deficiencies of the prior art, the purpose of the present application is to provide a chip removal head, a chip removal system and a chip removal method, so as to solve the problem in related arts of how to remove defective Micro LED chips without causing contamination to a display panel and damage to a bonding pad.

### Solution to the Problem

### Technical Solution

The present application provides a chip removal head, including: a heating portion and an attractive force guide portion, wherein
the heating portion includes a bottom surface and a top surface, which are opposite to each other, and the bottom surface is a surface in contact with a to-be-removed chip;
the heating portion is connected to an external power supply, and generates a dissociation heat under the action of the external power supply, wherein the dissociation heat is used for releasing a connection between the to-be-removed chip and an external substrate; and
the attractive force guide portion is configured to guide the to-be-removed chip, for which the connection has been released, to be adsorbed on the bottom surface of the heating portion.

The above chip removal head has the heating portion and the attractive force guide portion, the heating portion is connected to an external power supply, during a chip removal process, the bottom surface of the heating portion is in contact with the to-be-removed chip to be removed from a circuit board (for example, it can be, but is not limited to, a Micro LED chip), and generates a dissociation heat under the action of an external power supply, and the connection between the to-be-removed chip and the external substrate is released by means of the dissociation heat. The attractive force guide portion is configured to guide the to-be-removed chip, for which the connection has been released, to be adsorbed on the bottom surface of the heating portion, so that the to-be-removed chip can be removed from the substrate only by moving the heating portion. Neither the to-be-removed chip nor the corresponding bonding pad on the substrate will be damaged in the entire process, not only can the contamination to the entire substrate be avoided during the removal process, but it can also be ensured that the bonding pad corresponding to the chip on the substrate is not damaged, thereby ensuring that a repair process can be normally performed after the to-be-removed chip is removed.

Based on the same application concept, the present application further provides a chip removal system, including a control device, a mobile device and the chip removal head as described above, wherein

the control device is respectively connected to the chip removal head and the mobile device;
and the control device is configured to control the mobile device to drive the chip removal head to move, and control the chip removal head to release the connection between the to-be-removed chip and the substrate and adsorb the to-be-removed chip, for which the connection has been released, on the bottom surface of the heating portion.

In the above chip removal system, during a chip movement process, the control device can control the chip removal head to release the connection between the to-be-removed chip and the external substrate and adsorb the to-be-removed, for which the connection has been released, chip on the bottom surface of the heating portion, and can control the mobile device to drive the chip removal head to move, so as to remove the chip adsorbed on the chip removal head from the substrate. Neither the to-be-removed chip nor the corresponding bonding pad on the substrate will be damaged in the entire process, not only can the contamination to the entire substrate be avoided during the removal process of the to-be-removed chip, but it can also be ensured that the bonding pad corresponding to the chip on the substrate is not damaged, thereby ensuring that a repair process can be normally performed after the to-be-removed chip is removed; and furthermore, the control process is simple and efficient.

Based on the same application concept, the present application further provides a method for removing a chip by using the chip removal system as described above, including: controlling the mobile device to drive the chip removal head to move; and
controlling the chip removal head to release the connection between the to-be-removed chip and the substrate, and to adsorb the to-be-removed chip, for which the connection has been released, on the bottom surface of the heating portion.

In the above chip removal method, during a chip movement process, the chip removal head can be controlled to release the connection between the to-be-removed chip and the external substrate and adsorb the to-be-removed chip, for which the connection has been released, on the bottom surface of the heating portion, and the mobile device can be controlled to drive the chip removal head to move, so as to remove the chip adsorbed on the chip removal head from the substrate. Neither the to-be-removed chip nor the corresponding bonding pad on the substrate will be damaged in the entire chip removal process, not only can the contamination to the entire substrate be avoided during the removal process of the to-be-removed chip, but it can also be ensured that the bonding pad corresponding to the chip on the substrate is not damaged, thereby ensuring that a repair process can be normally performed after the to-be-removed chip is removed; and furthermore, the control process is simple and efficient.

### Advantages of the Invention

### Advantages

In the above chip removal head, chip removal system and chip removal method, during a chip movement process, the chip removal head can be controlled to release the connection between the to-be-removed chip and the external substrate and adsorb the to-be-removed chip, for which the connection has been released, on the bottom surface of the heating portion, and the mobile device can be controlled to drive the chip removal head to move, so as to remove the chip adsorbed on the chip removal head from the substrate. Neither the to-be-removed chip nor the corresponding bonding pad on the substrate will be damaged in the entire chip removal process, not only can the contamination to the entire substrate be avoided during the removal process of the to-be-removed chip, but it can also be ensured that the bonding pad corresponding to the chip on the substrate is not damaged, thereby ensuring that a repair process can be normally performed after the to-be-removed chip is removed; and furthermore, the control process is simple and efficient.

### BRIEF DESCRIPTION OF THE DRAWINGS

### Description of the Drawings

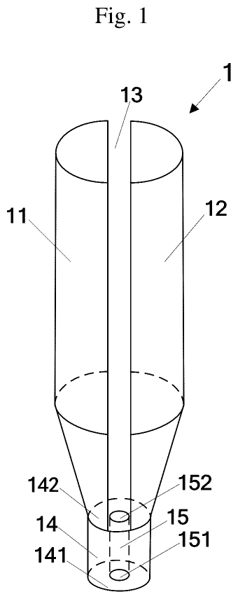

FIG. 1 is a first schematic structural diagram of a chip removal head provided by an embodiment of the present application;

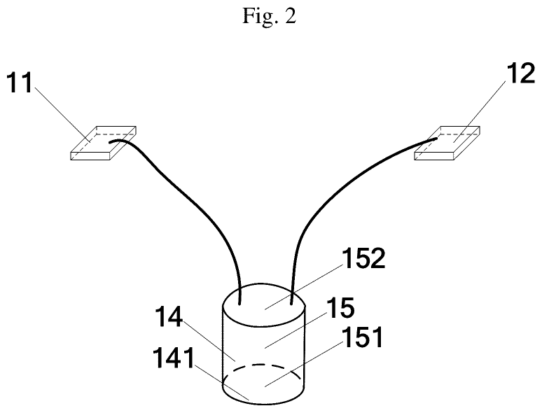

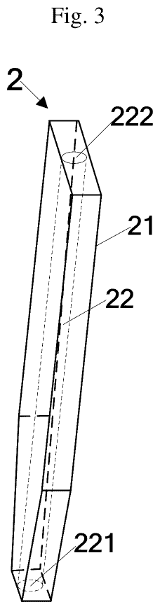

FIG. 2 is a second structural schematic diagram of a chip removal head provided by an embodiment of the present application;

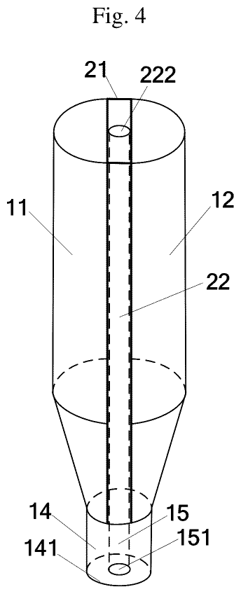

FIG. 3 is a first schematic structural diagram of an insulating embedding portion provided by an embodiment of the present application;

FIG. 4 is a third schematic structural diagram of a chip removal head provided by an embodiment of the present application;

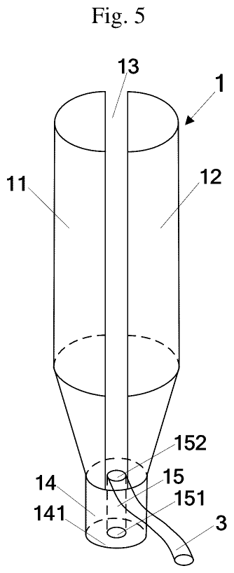

FIG. 5 is a fourth schematic structural diagram of a chip removal head provided by an embodiment of the present application;

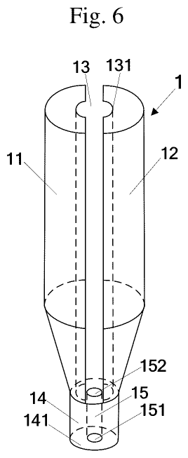

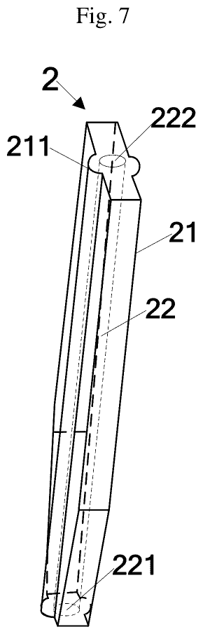

FIG. 6 is a fifth schematic structural diagram of a chip removal head provided by an embodiment of the present application;

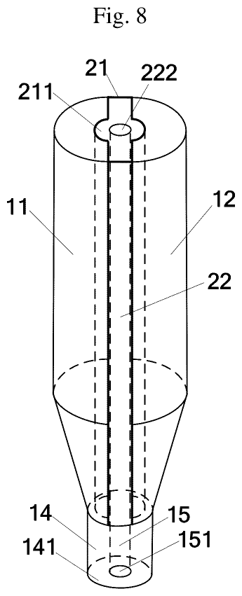

FIG. 7 is a second structural schematic diagram of an insulating embedding portion provided by an embodiment of the present application;

FIG. 8 is a sixth schematic structural diagram of a chip removal head provided by an embodiment of the present application;

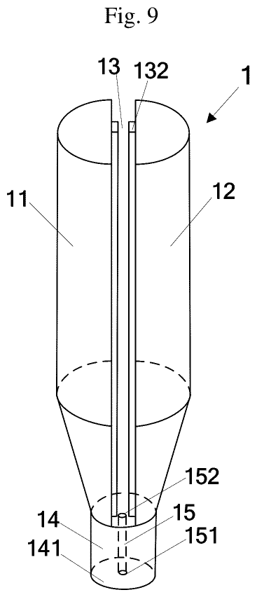

FIG. 9 is a seventh schematic structural diagram of a chip removal head provided by an embodiment of the present application;

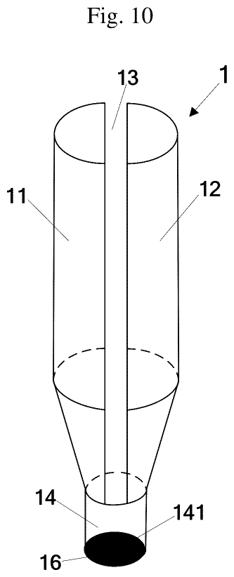

FIG. 10 is an eighth schematic structural diagram of a chip removal head provided by an embodiment of the present application; and

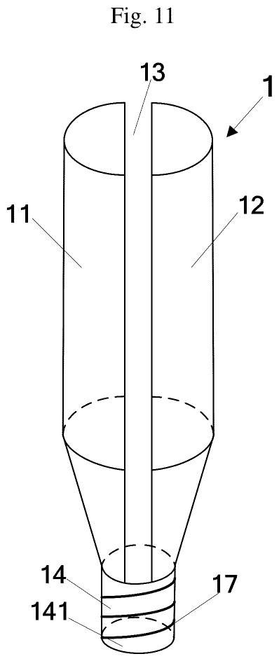

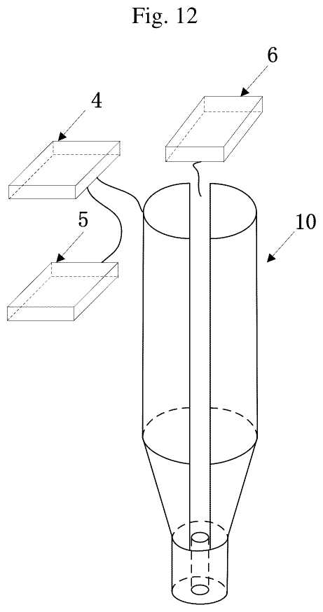

FIG. 11 is a ninth schematic structural diagram of a chip removal head provided by an embodiment of the present application.

### DESCRIPTION OF REFERENCE SIGNS

1—electrode portion, 11—positive electrode portion, 12—negative electrode portion, 13—gap, 14—heating portion, 141—bottom surface of the heating portion, 142—top surface of the heating portion, 15—first channel, 16—permanent magnet material layer, 17—conductive winding, 151—first channel port, 152—second channel port, 2—insulating embedding portion, 21—main body of the insulating embedding portion, 22—second channel, 221—third channel port, 222—fourth channel port, 3—connecting pipe, 131—first groove, 132—first protrusion, 211—second protrusion.

### EMBODIMENTS OF THE INVENTION

### Detailed Description of the Embodiments of the Invention

In order to conveniently understand the present application, the present application will be described more comprehensively below with reference to related drawings. Preferred embodiments of the present application are given in the drawings. However, the present application can be implemented in many different forms and is not limited to the embodiments described herein. Rather, these embodiments are provided, so that the understanding on the disclosure of the present application is more thorough and comprehensive.

Unless otherwise defined, all technical and scientific terms used herein have the same meanings as commonly understood by those skilled in the technical field to which the present application belongs. The terms used herein in the specification of the present application are for the purpose of describing specific embodiments only, and are not intended to limit the present application.

In related arts, for the removal of a defective Micro LED chip on a display panel, the Micro LED chip is usually pushed off by a mechanical force, or the Micro LED chip is removed by laser, so the Micro LED chip will be damaged during a removal process, resulting in irregular splash of the Micro LED chip to be removed or fragments thereof, which leads to contamination to the entire display panel. In addition, a bonding pad connected to the Micro LED chip on the display panel is also easily damaged by an external force, such that a new Micro LED chip disposed at this position thereafter cannot be normally electrically connected to a display backplane, thus affecting subsequent repairs.

In view of this, the present application hopes to provide a solution that can solve the above technical problems, and the details thereof will be described in subsequent embodiments.

The present embodiment provides a chip removal head, which can be used for removing a to-be-removed chip from a substrate. It should be understood that, the substrate in the present embodiment can be, but is not limited to, a circuit board, and the circuit board can be, but is not limited to, a display backplane (which can be a glass backplane or a PCB backplane or the like), a circuit board for lighting, or other functional circuit boards. Moreover, the circuit board in the present embodiment can be a flexible circuit board or a rigid circuit board. The to-be-removed chip in the present embodiment can include, but is not limited to, a defective chip, a chip with a wrong position, or chips that need to be removed under other circumstances. The to-be-removed chip in the present embodiment can be, but is not limited to, a light-emitting chip, a resistor chip, a driving chip, a capacitor chip, and the like. When the to-be-removed chip is a light-emitting chip, it can be an ordinary-sized LED chip with a chip size greater than 200 microns or a large-sized LED chip, or a micro light-emitting chip with a chip size less than or equal to 200 microns, such as a Mini LED chip or a Micro LED chip. For ease of understanding, the present embodiment is described below by taking it as an example that a substrate connected to the to-be-removed chip is a circuit board.

The chip removal head provided by the present embodiment includes a heating portion and an attractive force guide portion, wherein:
the heating portion is made of a conductive material, is connected to an external power supply, and generates a dissociation heat under the action of the external power supply, that is, the heat is generated when the heating portion is conducted with the external power supply, and the dissociation heat is used for releasing a connection between the to-be-removed chip and the circuit board (that is, the to-be-removed chip is disposed on the circuit board). In the present embodiment, the step of releasing the connection between the to-be-removed chip and the circuit board by means of the dissociation heat includes: heating a connection point between the to-be-removed chip and the circuit board by means of the dissociation heat, so as to reduce a bonding force of the connection point. For example, in some application scenarios, when the to-be-removed chip is soldered, by means of its electrodes, with a bonding pad on the circuit board by means of soldering flux or is bonded with the bonding pad by a conductive adhesive, the connection point at this time includes, but is not limited to, a point where the to-be-removed chip is connected to the corresponding bonding pad on the circuit board by means of the soldering flux or the conductive adhesive. In this application scenario, the soldering flux or the conductive adhesive is heated by the dissociation heat, so as to reduce its bonding force.

It should be understood that in the present embodiment, the resistance value of the heating portion can be flexibly selected according to factors such as the temperature of the required heat and the time for generating the heat, which is not limited in the present embodiment. For example, in an application example, the heating portion can be made of, but is not limited to, an alloy containing tungsten and molybdenum, into which current is injected when it is conducted with the external power supply, and heat is generated by the high resistance value of the heating portion so as to form a high temperature; the voltage, the conduction time and the like of the external power supply can be controlled to adjust an instantaneous high temperature value of the heating portion; and due to the use of the alloy containing tungsten and molybdenum, it is possible to ensure a long service life and a stable work for the heating portion at the high temperature. Of course, it should be understood that the material of the heating portion in the present embodiment can also be equivalently replaced with other materials according to requirements, which will not be repeated herein.

In some examples of the present embodiment, the chip removal head can further include an electrode portion, the electrode portion can include a positive electrode portion and a negative electrode portion, which are insulated from each other, and the heating portion can form an electrical connection with the external power supply by means of the positive electrode portion and the negative electrode portion.

In the present embodiment, the heating portion includes a bottom surface and a top surface, which are opposite to each other, and the bottom surface of the heating portion is in contact with the to-be-removed chip during a chip removal process, that is, the bottom surface of the heating portion is a surface in contact with the to-be-removed chip; and the attractive force guide portion is configured to guide the to-be-removed chip, for which the connection has been released, to be adsorbed on the bottom surface of the heating portion. Therefore, the to-be-removed chip can be removed from the circuit board only by moving the heating portion; and neither the to-be-removed chip nor the corresponding bonding pad on the circuit board will be damaged in the entire process, not only can the contamination to the entire circuit board be avoided during the removal process of the to-be-removed chip, but it can also be ensured that the bonding pad on the circuit board is not damaged, thereby ensuring that a repair process can be normally performed after the to-be-removed chip is removed.

It should be understood that in the present embodiment, the bottom surface of the heating portion can be in contact with the to-be-removed chip during the entire chip removal process, or, during the chip removal process, the bottom surface of the heating portion is in contact with the to-be-removed chip only when the to-be-removed chip is adsorbed on the bottom surface of the heating portion. For example, in an application scenario, when the to-be-removed chip is removed from the circuit board by using the chip removal head, the heating portion is moved to the position of the to-be-removed chip that is to be removed from the circuit board, so that the bottom surface of the heating portion faces the to-be-removed chip, and the bottom surface of the heating portion can be in direct contact with the to-be-removed chip, or there can be a small gap with the to-be-removed chip. The heating portion generates heat under the action of the current that flows into the conducted external power supply, and transfers the generated heat to the connection point of the to-be-removed chip on the circuit board, thereby reducing the bonding force of the connection point (that is, releasing the connection between the to-be-removed chip and the circuit board), and the to-be-removed chip is adsorbed on the bottom surface of the heating portion under the guidance of the attractive force guide portion. In this way, after the bonding force of the connection point is reduced to a certain extent, the to-be-removed chip can be removed from the circuit board only by moving the heating portion.

For example, in an application example, the electrode of the to-be-removed chip is connected to the corresponding bonding pad on the circuit board by the soldering flux, at this time, the connection point between the electrode of the to-be-removed chip and the corresponding bonding pad on the circuit board is a soldering spot formed by the soldering flux, and the dissociation heat is transferred to the soldering spot to melt the soldering flux, so as to release the connection between the chip to be transferred and the circuit board.

As another example, in another application example, the electrode of the to-be-removed chip is connected to the corresponding bonding pad on the circuit board by the conductive adhesive, at this time, the connection point between the electrode of the to-be-removed chip and the corresponding bonding pad on the circuit board is a bonding point formed by the conductive adhesive, and the dissociation heat is transferred to the bonding point to melt the conductive adhesive, so as to release the connection between the chip to be transferred and the circuit board.

Of course, it should be understood that, the connection manners between the electrode of the to-be-removed chip and the corresponding bonding pad on the circuit board are not limited to the above two examples, and can be equivalently replaced by other manners, which will not be repeated herein.

In the present embodiment, the attractive force guide portion can use, but is not limited to, a vacuum adsorption force, a magnetic force, and the like, to guide the to-be-removed chip, for which the connection has been released, to be adsorbed on the bottom surface of the heating portion. For ease of understanding, the present embodiment is described below by taking the vacuum adsorption force and the magnetic force as examples, respectively.

An example of a chip removal head shown in FIG. 1, an electrode portion 1 includes a positive electrode portion 11 and a negative electrode portion 12, which are insulated from each other, and the positive electrode portion 11 and the negative electrode portion 12 are electrically connected to a power supply. In FIG. 1, insulated isolation between the positive electrode portion 11 and the negative electrode portion 12 is realized by a gap 13 therebetween. Of course, in some examples, the insulated isolation therebetween can also be realized by other insulating substances. A heating portion 14 in FIG. 1 is electrically connected to the positive electrode portion 11 and the negative electrode portion 12 at the same time.

In FIG. 1, the positive electrode portion 11 and the negative electrode portion 12 are respectively a positive electrode column and a negative electrode column, lower ends of the positive electrode column and the negative electrode column are respectively fixed on a top surface 142 of the heating portion 14, and upper ends of the positive electrode column and the negative electrode column are electrically connected to the power supply; and there is a gap 13 between the positive electrode column and the negative electrode column to form the insulated isolation therebetween. By means of this structural setting, the resistance at the position of the heating portion 14 is the largest, and the current generates heat instantaneously (for example, it can reach a millisecond level) at the position of the heating portion 14, and the heating portion 14 transfers the heat (i.e., dissociation heat) to the connection point of the to-be-removed chip on the circuit board, so as to reduce the bonding force thereof.

It should be understood that in the present embodiment, the positive electrode portion 11 and the negative electrode portion 12 are not limited to the structures of the positive electrode column and the negative electrode column shown in FIG. 1, and can also be set to be other structures as needs. For example, an example is shown in FIG. 2, the positive electrode portion 11 and the negative electrode portion 12 can be electrically connected to the heating portion 14 respectively by means of, but not limited to, wires or other conductive materials.

For ease of understanding, the present embodiment is described below by taking the chip removal head shown in FIG. 1 as an example. It should be understood that the heating portion 14, the positive electrode column and the negative electrode column in FIG. 1 can be made of the same material, and can be integrally formed or of non-integrated structures. Of course, in some other examples, the materials of the heating portion 14, the positive electrode column and the negative electrode column can also be the same, which will not be repeated herein.

Referring to FIG. 1, the attractive force guide portion of the chip removal head includes a first channel 15 penetrating through the bottom surface 141 and the top surface 142 of the heating portion 14, and the bottom surface 141 and the top surface 142 of the heating portion 14 are two opposite surfaces, wherein:
a second channel port 152 of the first channel 15 located on the top surface 142 of the heating portion 14 is connected to a negative pressure device, and a first channel port 151 of the first channel 15 located on the bottom surface 141 of the heating portion 14 generates a vacuum adsorption force under the action of the negative pressure device; and during the chip removal process, the first channel port 151 corresponds to the to-be-removed chip, the aperture of the first channel port 151 matches the size of the top surface of the to-be-removed chip, and the top surface of the to-be-removed chip is a surface of the to-be-removed chip that faces the bottom surface 141 of the heating portion 14.

The negative pressure device in the present embodiment can be various devices that form a negative pressure in the first channel 15 to generate the vacuum adsorption force, for example, but is not limited to, a vacuum pump. For ease of understanding, the present embodiment is described by taking it as an example that the negative pressure device in subsequent content is a vacuum pump.

In the present embodiment, the aperture of the first channel port 151 matches the size of the top surface of the to-be-removed chip, which means that the maximum aperture of the first channel port 151 is less than the maximum size of the top surface of the to-be-removed chip (for example, when the top surface of the to-be-removed chip is a rectangle, the maximum aperture of the first channel port 151 is less than the length or width or diagonal of the rectangle), so that the to-be-removed chip is adsorbed on the bottom surface 141 of the heating portion 14.

In an example of the present embodiment, the second channel port 152 of the first channel 15 can be connected to the negative pressure device by means of a connecting pipe. For example, as shown in FIG. 5, the second channel port 152 of the first channel 15 can be connected to the negative pressure device by means of a connecting pipe 3.

In another example of the present embodiment, as shown in FIG. 3, the attractive force guide portion includes an insulating embedding portion 2 on which a second channel 22 is formed, the second channel 22 is formed in a main body 21 of the insulating embedding portion 2, and penetrates through the upper and lower ends of the insulating embedding portion 2. As shown in FIG. 4, the insulating embedding portion 2 is embedded in the gap 13, the lower end of the insulating embedding portion 2 is close to the top surface 142 of the heating portion 14, a third channel port 221 of the second channel 22 is located on the lower end of the insulating embedding portion 2 and is in butt joint with the second channel port 152 of the first channel 15, a fourth channel port 222 of the second channel 22 is located on the upper end of the insulating embedding portion 2 and is connected to the negative pressure device, for example, can also be connected to the negative pressure device by means of, but not limited to, the connecting pipe. In this way, the first channel 15 is connected to the negative pressure device by means of the second channel 22.

In the present embodiment, the insulating embedding portion 2 can be made of a high-temperature resistant insulating material. For example, in some application scenarios, the insulating embedding portion 2 can be made of, but is not limited to, high-temperature ceramics, polyether ether ketone or quartz. In some other application scenarios, the insulating embedding portion 2 can also be composed of a composite layer formed by a conductive layer and an insulating layer. For example, the conductive layer forms the second channel, the insulating layer wraps the conductive layer, and the insulating layer and the conductive layer can be made of high-temperature resistant materials.

In some examples of the present embodiment, in order to improve the stability and reliability of fixing the insulating embedding portion 2 in the gap 3, after the insulating embedding portion 2 is embedded in the gap, the insulating embedding portion 2 forms interference fit with the positive electrode column and the negative electrode column, such that the insulating embedding portion 2 is firmly embedded in the gap 13.

In some examples of the present embodiment, in order to improve the stability and reliability of fixing the insulating embedding portion 2 in the gap 3, two opposite side surfaces of the positive electrode column and the negative electrode column form side walls of the gap; at least one of the side walls is provided with a first groove and/or a first protrusion that extends toward the top surface of the heating portion; and at least one outer side wall of the insulating embedding portion opposite to the side walls of the gap 13 is provided with a second protrusion and/or a second groove that extends toward the lower end of the insulating embedding portion, wherein:
the first groove corresponds to the second protrusion, and the first protrusion corresponds to the second groove; and when the insulating embedding portion is embedded in the gap, if the first groove and the second protrusion are provided, the second protrusion is clamped in the first groove, and/or, if the first protrusion and the second groove are provided, the first protrusion is clamped in the second groove.

For ease of understanding, the following description is given in conjunction with two setting examples.

An example is shown in FIG. 6 to FIG. 8, wherein as shown in FIG. 6, two opposite side surfaces of the positive electrode column and the negative electrode column are provided with first grooves 131 that extend from top to bottom (or only one of the side surfaces is provided with the first groove 131), and as shown in FIG. 7, two outer walls (or only one of the outer walls) of the insulating embedding portion 2 opposite to the side wall of the gap 13 are provided with second protrusions 211 that extend toward the lower end of the insulating embedding portion 2; and as shown in FIG. 8, when the insulating embedding portion 2 is embedded in the gap 13, the second protrusion 211 is clamped in the first groove 131.

Another example is shown in FIG. 9, wherein as shown in FIG. 9, two opposite side surfaces of the positive electrode column and the negative electrode column are provided with first protrusions 132 that extend from top to bottom (or only one of the side surfaces is provided with the first protrusion 132). In the present application example, two outer walls (or only one of the outer walls) of the insulating embedding portion 2 opposite to the side wall of the gap 13 are provided with second grooves (not shown in the figure), which extend toward the lower end of the insulating embedding portion 2 and correspond to the first protrusions, and when the insulating inserting portion 2 is embedded in the gap 13, the first protrusion 132 is clamped in the second groove 132.

It should be understood that, the numbers of the above corresponding first protrusions and second grooves and/or the corresponding first grooves and second protrusions can be flexibly selected according to specific conditions, and optionally, the first protrusions, the second grooves, the first grooves and the second protrusions are provided at the same time, which will not repeated herein. Moreover, it should be understood that the specific shapes of the first protrusions, the second grooves, the first grooves and the second protrusions in the present embodiment can be set flexibly, and the shapes thereof are not limited in the present embodiment.

In the present embodiment, the cross-sectional shapes of the positive electrode column and the negative electrode column are arcs, and the sizes thereof can be flexibly set according to application scenarios. For example, in some examples, the cross-sectional shapes of the positive electrode column and the negative electrode column can be the same or different, and the cross-sectional shapes of the positive electrode column and the negative electrode column can be arcs (including semi-circles and non-semi-circles), rectangles, triangles, rhombuses and other regular shapes, and can also be irregular shapes, which will not be repeated herein.

In some examples of the present embodiment, in order to make the chip removal head better match the to-be-removed chip, reserve a more abundant operating space, and minimize the impact on other chips adjacent to the to-be-removed chip during the chip removal process as much as possible, the cross-sectional sizes of the positive electrode column and the negative electrode column close to their lower ends can be gradually reduced. For example, as shown in FIG. 4, the cross-sectional shapes of the positive electrode column and the negative electrode column are arcs, and the cross-sectional sizes of the positive electrode column and the negative electrode column close to their lower ends are gradually reduced to form a shape similar to a cone. In the present example, reference can also be made to the settings of the positive electrode column and the negative electrode column for the insulating embedding portion 2 disposed in the gap 13, and the shape and size of the insulating embedding portion 2 can be adapted to those of the gap 13, and the insulating embedding portion 2 can completely fill the gap 13 or only a part of it.

In an example of the present embodiment, the shape of the heating portion can also be set flexibly. For example, the heating portion can be a cylindrical heating portion or a conical heating portion, and the cross-sectional size of the upper end of the heating portion is adapted to those of the lower ends of the positive electrode column and the negative electrode column. For example, as shown in FIG. 4 for an application scenario, the heating portion 14 is cylindrical, and the cross-sectional size of the upper end of the heating portion 14 is adapted to those of the lower ends of the positive electrode column and the negative electrode column, that is, an outer edge of the upper end of the heating portion 14 is coplanar with the outer edges of the lower ends of the positive electrode column and the negative electrode column. In addition, the heating portion 14, the positive electrode column and the negative electrode column can be integrally formed. In this way, during production, a complete conductive metal rod can be simply processed directly, so as to obtain the chip removal head shown in FIG. 1, the production process of the chip removal head is simple, the cost is low, and the overall structure and integrity of the chip removal head are good.

When the chip removal head in the above examples is used to remove the to-be-removed chip that is to be removed from the circuit board, the heating portion 14 is moved to the position of the to-be-removed chip that is to be removed from the circuit board, so that the bottom surface 141 of the heating portion 14 faces the to-be-removed chip, and the bottom surface of the heating portion can be in direct contact with the to-be-removed chip (or is not in contact with the to-be-removed chip, as long as heat transfer and attractive force adsorption can be ensured). Under the action of the current flowing into the conducted positive electrode portion 11, the negative electrode portion 12 and the power supply, the heating portion generates heat, and transfers the generated heat to the connection point of the to-be-removed chip on the circuit board, so as to reduce the bonding force of the connection point. The to-be-removed chip is adsorbed on the bottom surface 141 of the heating portion 14 under the guidance of the vacuum adsorption force that is generated by the negative pressure device by means of the first channel and the second channel (i.e., the attractive force guide portion), and after the bonding force of the connection point is reduced to a certain extent, when the vacuum adsorption force is greater than the bonding force of the connection point, the to-be-removed chip can be removed from the circuit board only by moving the heating portion 14. Neither the to-be-removed chip nor the corresponding bonding pad on the circuit board will be damaged in the entire process, not only can the contamination to the entire circuit board be avoided during the removal process of the to-be-removed chip, but it can also be ensured that the bonding pad on the circuit board is not damaged, thereby ensuring that a repair process can be normally performed after the to-be-removed chip is removed. After the to-be-removed chip is removed from the circuit board by moving the heating portion 14, the negative pressure device can be controlled to be turned off, so that the generated vacuum adsorption force disappears, and then the to-be-removed chip is released from the chip removal head. For example, after the chip removal head is moved to a corresponding chip recovery position, the to-be-removed chip is released from the chip removal head and placed on the chip recovery position.

For ease of understanding, the present embodiment is described by taking it as an example that the attractive force guide portion uses a magnetic force to guide the to-be-removed chip, for which the connection has been released, to be adsorbed on the bottom surface of the heating portion.

In an application example, as shown in FIG. 10, the attractive force guide portion includes a permanent magnet material layer 16 that is disposed on the bottom surface 141 of the heating portion 14 for generating a magnetic attractive force; and the permanent magnet material layer 16 matches a magnetic layer structure (such as a metal electrode, or other layer structures disposed in the to-be-removed chip) that can be adsorbed by the magnetic force on the to-be-removed chip, so that the to-be-removed chip is guided by an attractive force generated by the permanent magnet material layer 16, so as to adsorbed on the bottom surface 141 of the heating portion 14. In the present application example, after the to-be-removed chip is removed from the circuit board by moving the heating portion 14, the to-be-removed chip can be released from the chip removal head by an external force or other means. In the present example, the permanent magnet material can be disposed on the bottom surface 141 of the heating portion 14 by sputtering or other manners.

It should be understood that, the permanent magnet material layer 16 in the present application example can cover the entire bottom surface 141 of the heating portion 14, or only a part of it, as long as the permanent magnet material layer 16 can match the corresponding to-be-removed chip, so as to adsorb the to-be-removed chip on the bottom surface 141 of the heating portion 14.

It should be understood that, in the present application example, the material of the permanent magnet material layer 16 can be set flexibly. For example, the permanent magnet material layer 16 can be made of, but is not limited to, metal alloy magnets, which can include, but are not limited to, at least one of the following:
neodymium-iron-boron magnet: it is a magnet with the strongest magnetism at present, and thus is called a magnet king. It has extremely high magnetic properties and its maximum magnetic energy product is more than 10 times higher than that of ferrite. The machining property of the neodymium-iron-boron magnet is very good. The working temperature can reach up to 200° C. Moreover, the texture is hard, and the performance is stable, thereby having very good cost performance. But because of its strong chemical activity, a surface coating of which can be treated, such as zinc (Zn), nickel (Ni), epoxy and so on.

Ferrite magnet: the main raw materials include BaO or SrO and Fe₂O₃. The ferrite magnet is manufactured by a ceramic process method, the texture is relatively hard, and thus belongs to a brittle material. Because of its good temperature resistance, low price and moderate performance, the ferrite magnet has become the most widely used permanent magnet.

Aluminium-nickel-cobalt magnet: it is an alloy composed of aluminum, nickel, cobalt, iron and other trace metal elements. It can be processed into different sizes and shapes by a casting process, so that the machinability is very good. The aluminium-nickel-cobalt magnet has the lowest reversible temperature coefficient, and the working temperature can reach up to 600° C. Aluminium-nickel-cobalt permanent magnet products are widely used in various instruments and other application fields.

Samarium-cobalt magnet: as a rare earth permanent magnet, the samarium-cobalt magnet not only has higher magnetic energy product, reliable coercivity and good temperature characteristics. Compared with the neodymium-iron-boron magnet, the samarium-cobalt magnet is more suitable for working in high temperature environments.

In another application example, as shown in FIG. 11, the attractive force guide portion includes a conductive winding 17 disposed on the heating portion 14, and the bottom surface 141 of the heating portion 14 generates a magnetic attractive force when the conductive winding is powered on. That is, the heating portion 14 and the conductive winding 17 disposed thereon together constitute an electromagnet. The conductive winding 17 can be a solenoid, and when the heating portion 14 made of a metal material is inserted into the powered-on solenoid, the heating portion 14 is magnetized by a magnetic field of the powered-on solenoid; and the magnetized heating portion 14 also becomes a magnet. In this way, since the two magnetic fields are superimposed on each other, the magnetism of the solenoid is greatly enhanced. The electromagnet is a device that can generate a magnetic force by injecting current, belongs to a non-permanent magnet, and its magnetism can be easily activated or eliminated, that is, the electromagnet has the characteristic that the magnetism is generated in the case of power on and the magnetism disappears in the case of power off. Moreover, the magnetic field generated by the electromagnet is related to the size of the current, the number of coil turns and a ferromagnet in the center. When the electromagnet is designed, the distribution of the coils and the selection of the ferromagnet (i.e., the heating portion 14) can be set according to the current requirements, and the magnetic field can be controlled by the magnitude of the current.

In the present application example, two electrical connection ends of the conductive winding 17 can be electrically connected to the positive electrode portion 11 and the negative electrode portion 12 respectively, thereby improving the integration degree of the chip removal head. In another example of the present embodiment, the two electrical connection ends of the conductive winding 17 can also be connected to the power supply independently, which can be flexibly set according to application requirements.

When the chip removal head in the present application example is used to remove the to-be-removed chip that is to be removed from the circuit board, the heating portion 14 is moved to the position of the to-be-removed chip that is to be removed from the circuit board, so that the bottom surface 141 of the heating portion 14 faces the to-be-removed chip, and the bottom surface of the heating portion can be in direct contact with the to-be-removed chip or is not contact with the to-be-removed chip, the heating portion 14 generates heat under the action of the current that flows into the conducted positive electrode portion 11, the negative electrode portion 12 and the power supply, and transfers the generated heat to the connection point of the to-be-removed chip on the circuit board, thereby reducing the bonding force of the connection point, and the to-be-removed chip is adsorbed on the bottom surface of the heating portion 14 under the guidance of the attractive force guide portion after the conductive winding 17 is powered on, and after the bonding force of the connection point is reduced to a certain extent, when the magnetic attractive force is greater than the bonding force of the connection point, the to-be-removed chip can be removed from the circuit board only by moving the heating portion 14. Neither the to-be-removed chip nor the corresponding bonding pad on the circuit board will be damaged in the entire process, not only can the contamination to the entire circuit board be avoided during the removal process of the to-be-removed chip, but it can also be ensured that the bonding pad on the circuit board is not damaged, thereby ensuring that a repair process can be normally performed after the to-be-removed chip is removed. After the to-be-removed chip is removed from the circuit board by moving the heating portion 14, the conducive winding 17 can be controlled to be turned off, so that the generated magnetic attractive force disappears, and then the to-be-removed chip is released from the chip removal head. For example, after the chip removal head is moved to the corresponding chip recovery position, the to-be-removed chip is released from the chip removal head and placed on the chip recovery position.

### Another Optional Embodiment

The present embodiment provides a chip removal system, including a control device, a mobile device, and the chip removal head shown in the above embodiment, wherein:
the control device is respectively connected to the chip removal head and the mobile device. It should be understood that, in some examples of the present embodiment, the control device can be directly connected to the chip removal head and the mobile device, respectively, or can be connected to the chip removal head by means of the mobile device, or connected to the mobile device by means of the chip removal head.

The control device is configured to control the mobile device to drive the chip removal head to move. For example, the control device controls the mobile device to drive the chip removal head to move to the position of the to-be-removed chip, and to move away from the position of the to-be-removed chip. The control device is further configured to control the chip removal head to release the connection between the to-be-removed chip and the substrate and adsorb the to-be-removed chip, for which the connection has been released, on the bottom surface of the heating portion.

A method for removing a chip by using the chip removal system described above includes:
controlling the mobile device to drive the chip removal head to move, so as to control the chip removal head to release the connection between the to-be-removed chip and the substrate and adsorb the to-be-removed chip, for which the connection has been released, on the bottom surface of the heating portion. For example, a control example is as follows:
controlling the mobile device to drive the chip removal head to move to the position of the to-be-removed chip, and controlling the positive electrode portion and the negative electrode portion to conduct with the external power supply, that is, controlling the heating portion to conduct with the external power supply; and
after the bonding force of the connection point of the to-be-removed chip on the circuit board is reduced by heating, and the to-be-removed chip is adsorbed on the bottom surface of the heating portion under the action of the attractive force, controlling the mobile device to drive the chip removal head to move away from the position of the to-be-removed chip, and controlling the positive electrode portion and the negative electrode portion to disconnect from the power supply.

It should be understood that, the control device in the present embodiment can be, but is not limited to, a background control platform, such as a background control host and a server. The mobile device in the present embodiment can be various devices that can drive the chip removal head to move, such as, but are not limited to, a mechanical arm and a moving track, as long as it can drive, under the control of the control device, the chip removal head to move to the position of the to-be-removed chip and move away from the position of the to-be-removed chip. For ease of understanding, the present embodiment is described below with the chip removal head as the structure shown in FIG. 4. In the present example, the chip removal system further includes a negative pressure device, and the chip removal process by using the chip removal system is as follows:
the chip removal head is electrically connected, including connecting the positive electrode portion and the negative electrode portion of the chip removal head to the positive and negative electrodes of the power supply, and connecting a first channel hole to the negative pressure device by means of the first channel and the second channel.

A mechanical motor (i.e., an example of the mobile device) drives the chip removal head to move to a target position to be removed and contact the to-be-removed chip that is to be removed.

Vacuum adsorption is started and current is injected into the positive and negative electrodes (the current can be injected into the positive and negative electrodes at the same time in the previous step, the current can also be injected into the positive and negative electrodes prior to the previous step, the current can also be injected into the positive and negative electrodes after the previous step; and correspondingly, the control of starting the vacuum adsorption is similar, and thus will not be described herein), the current generates a high temperature under the high resistance value of the heating portion, and the instantaneous high temperature value can be adjusted by controlling the voltage and time, so as to achieve the purpose of reducing the bonding force (for example, a soldering force of the soldering spot) of the connection point of the to-be-removed chip on the circuit board.

The mechanical motor drives the chip head to move away from the circuit board (prior to this step, the electrical connection among the positive electrode portion, the negative electrode portion and the power supply can be disconnected at first, or after this step, the electrical connection among the positive electrode portion, the negative electrode portion and the power supply can be disconnected, or the electrical connection among the positive electrode portion, the negative electrode portion and the power supply is disconnected only after all to-be-removed chips are removed), and the to-be-removed chip is removed from the circuit board under the action of the vacuum adsorption force.

After the mechanical motor drives the removal head to a defective product recovery position, the to-be-removed chip is released by de-vacuuming, and the above actions are repeated to remove the next dead pixel.

It should be understood that in the present embodiment, the chip removal system can perform other equivalent replacements. For example, in an application example, a mobile carrying platform can also be provided, the mobile carrying platform is used for carrying the circuit board, the control device can control the mobile carrying platform to move to the lower side of the chip removal head, and make the to-be-removed chip, which is to be removed from the circuit board, correspond to the chip removal head. Of course, in some other examples, both the chip removal head and the circuit board can also be controlled to move and move relative to each other, so that the to-be-removed chip, which is to be removed from the circuit board, corresponds to the chip removal head.

As another example, in some application examples, the chip removal head can also be the removal head shown in FIG. 10 or FIG. 11 that generates a magnetic attractive force, and its control process for chip removal is similar to the chip removal process in the above example, and thus will not be repeated herein.

It should be understood that, the application of the present application is not limited to the above examples. For those of ordinary skill in the art, improvements or transformations can be made according to the above description, and all these improvements and transformations should belong to the protection scope of the appended claims of the present application.

1. A chip removal head, comprising: a heating portion and an attractive force guide portion, wherein
the heating portion comprises a bottom surface and a top surface, which are opposite to each other, and the bottom surface is a surface in contact with a to-be-removed chip;
the heating portion is connected to an external power supply, and generates a dissociation heat under the action of the external power supply, wherein the dissociation heat is used for releasing a connection between the to-be-removed chip and an external substrate; and
the attractive force guide portion is configured to guide the to-be-removed chip, for which the connection has been released, to be adsorbed on the bottom surface of the heating portion;
wherein the attractive force guide portion comprises a permanent magnet material layer that is disposed on the bottom surface of the heating portion for generating a magnetic attractive force; or
wherein the attractive force guide portion comprises a conductive winding disposed on the heating portion, and the bottom surface of the heating portion generates a magnetic attractive force when the conductive winding is powered on.

2. The chip removal head according to claim 1, wherein the attractive force guide portion comprises a first channel penetrating through the bottom surface and the top surface;
a second channel port, located on the top surface, of the first channel is connected to a negative pressure device; and
a first channel port, located on the bottom surface, of the first channel is opposite to the to-be-removed chip, and generates a vacuum adsorption force under the action of the negative pressure device.

3. The chip removal head according to claim 2, wherein the chip removal head further comprises a positive electrode column and a negative electrode column;
a lower end of the positive electrode column and a lower end of the negative electrode column are respectively disposed on the top surface, and an upper end of the positive electrode column and an upper end of the negative electrode column are electrically connected to the external power supply; and
there is a gap between the positive electrode column and the negative electrode column for isolating the positive electrode column and the negative electrode column.

4. The chip removal head according to claim 3, wherein the heating portion, the positive electrode column and the negative electrode column are integrally formed.

5. The chip removal head according to claim 3, wherein the attractive force guide portion further comprises:
an insulating embedding portion on which a second channel is formed; and
the insulating embedding portion is embedded in the gap, a lower end of the insulating embedding portion is close to the top surface, a third channel port of the second channel is located on the lower end of the insulating embedding portion and is in butt joint with the second channel port, and a fourth channel port of the second channel is located on the upper end of the insulating embedding portion and is connected to the negative pressure device.

6. The chip removal head according to claim 3, wherein the heating portion, the positive electrode column and the negative electrode column are made of an alloy containing tungsten and molybdenum.

7. The chip removal head according to claim 5, wherein the insulating embedding portion is made of high-temperature ceramics, polyether ether ketone or quartz.

8. The chip removal head according to claim 5, wherein two opposite side surfaces of the positive electrode column and the negative electrode column form side walls of the gap;
at least one of the side walls is provided with a first groove and/or a first protrusion that extends toward the top surface;
at least one outer side wall of the insulating embedding portion opposite to the side walls is provided with a second protrusion and/or a second groove that extends toward the lower end of the insulating embedding portion; and
when the insulating embedding portion is embedded in the gap, the second protrusion is clamped in the first groove, and/or, the first protrusion is clamped in the second groove.

9. The chip removal head according to claim 5, wherein after the insulating embedding portion is embedded in the gap, the insulating embedding portion forms interference fit with the positive electrode column and the negative electrode column.

10. The chip removal head according to claim 3, wherein a cross-sectional shape of the positive electrode column and a cross-sectional shape of the negative electrode column are arcs, and a cross-sectional size of the lower end of the positive electrode column and a cross-sectional size of the lower end of the negative electrode column are gradually reduced.

11. The chip removal head according to claim 10, wherein the heating portion is a cylindrical heating portion or a conical heating portion, and a cross-sectional size of an upper end of the heating portion is adapted to those of the lower end of the positive electrode column and the lower end of the negative electrode column.

12. (canceled)

13. (canceled)

14. The chip removal head according to claim 1, wherein two electrical connection ends of the conductive winding are electrically connected to the positive electrode portion and the negative electrode portion, respectively.

15. A chip removal system, comprising a control device, a mobile device and the chip removal head according to claim 1;
the control device is respectively connected to the chip removal head and the mobile device; and the control device is configured to control the mobile device to drive the chip removal head to move, and control the chip removal head to release the connection between the to-be-removed chip and the substrate and adsorb the to-be-removed chip, for which the connection has been released, on the bottom surface of the heating portion.

16. The chip removal system according to claim 15, wherein the chip removal system further comprises a negative pressure device, and the attractive force guide portion comprises a first channel penetrating through the bottom surface of the heating portion and the top surface of the heating portion; and
a second channel port, located on the top surface of the heating portion, of the first channel is connected to the negative pressure device, and a first channel port, located on the bottom surface of the heating portion, of the first channel generates a vacuum adsorption force under the action of the negative pressure device.

17. A method for removing a chip by using the chip removal system according to claim 15, comprising:
controlling the mobile device to drive the chip removal head to move; and
controlling the chip removal head to release the connection between the to-be-removed chip and the substrate and adsorb the to-be-removed chip, for which the connection has been released, on the bottom surface of the heating portion.

18. The chip removal system according to claim 16, wherein the chip removal head further comprises a positive electrode column and a negative electrode column;
a lower end of the positive electrode column and a lower end of the negative electrode column are respectively fixed disposed on the top surface, and an upper end of the positive electrode column and an upper end of the negative electrode column are electrically connected to the external power supply; and
there is a gap between the positive electrode column and the negative electrode column for isolating the positive electrode column and the negative electrode column.

19. The chip removal system according to claim 18, wherein the heating portion, the positive electrode column and the negative electrode column are integrally formed.

20. The chip removal system according to claim 18, wherein the attractive force guide portion further comprises:
an insulating embedding portion on which a second channel is formed; and
the insulating embedding portion is embedded in the gap, a lower end of the insulating embedding portion is close to the top surface, a third channel port of the second channel is located on the lower end of the insulating embedding portion and is in butt joint with the second channel port, and a fourth channel port of the second channel is located on the upper end of the insulating embedding portion and is connected to the negative pressure device.
